(19) United States
(12) Patent Application Publication
(10) Pub. No.: US 2025/0191916 A1
(43) Pub. Date: Jun. 12, 2025

(54) SEMICONDUCTOR APPARATUS AND METHOD FOR PRODUCING THE SAME

(71) Applicant: Mitsubishi Electric Corporation, Tokyo (JP)

(72) Inventors: Kazuhiro NISHIMURA, Fukuoka (JP); Norikazu SAKAI, Tokyo (JP); Makoto UENO, Fukuoka (JP); Yukimasa HIGASHI, Tokyo (JP); Koji YAMAMOTO, Tokyo (JP)

(73) Assignee: Mitsubishi Electric Corporation, Tokyo (JP)

(21) Appl. No.: 18/840,351

(22) PCT Filed: Jun. 14, 2022
(86) PCT No.: PCT/JP2022/023813

§ 371 Date: Aug. 21, 2024

(51) Int. Cl. H01L 21/02; B23K 26/352; H01L 21/304; H01L 21/56; H01L 23/00; H01L 23/31; H01L 23/367; H01L 23/495; H01L 23/528

(52) U.S. Cl. CPC H01L 21/02686; B23K 26/352; H01L 21/304; H01L 21/56; H01L 23/49562; H01L 23/528; H01L 23/5283; H01L 23/3121; H01L 23/3677; H01L 24/04; H01L 24/32; H01L 24/45; H01L 24/48; H01L 24/73; H01L 2224/04042; H01L 2224/32245; H01L 2224/45124; H01L 2224/48091; H01L 2224/48245; H01L 2224/73265; H01L 2924/351

(57) ABSTRACT

The present disclosure relates to a semiconductor apparatus and a method for producing the same and has as its object to provide a semiconductor apparatus and a method for producing the same capable of achieving reduction in semiconductor apparatus costs and enhancement in ease of assembly by modifying an outermost surface of a front electrode by laser irradiation. The semiconductor apparatus of the present disclosure includes a front electrode solder-joined portion of the present disclosure, solder, a resin sealing material, and a semiconductor device which is mounted underneath the front electrode solder-joined portion. The front electrode solder-joined portion has a first laser-modified portion whose outermost surface is oxidized and roughened and a first solder-joined region which is joined to the solder, and the laser-modified portion is covered with the resin sealing material.

### FIELD

The present disclosure relates to a semiconductor apparatus and a method for producing the same and, more particularly, to a semiconductor apparatus suitable for use in a power converter, such as an inverter, and a method for producing the same.

### BACKGROUND

As a power semiconductor apparatus for use in, e.g., an inverter, an apparatus having a structure such that a front electrode of a semiconductor device is joined to an external electrode with solder has been known. If a semiconductor apparatus having such a structure is subjected to heat stress from a power cycle, a thermal cycle, or the like, thermal stress arising from a difference in coefficient of linear expansion between materials is generated. As a result, a material interface peels off at an outermost peripheral portion of a front electrode. When the peeling develops, the problem of, e.g., a front electrode crack in a semiconductor device occurs.

PTL 1 and PTL 2 disclose a technique for forming a covering film made of polyimide at a material boundary portion on a front electrode outermost periphery as an approach for preventing a front electrode crack in a semiconductor device.

### CITATION LIST

### Patent Literature

[PTL 1] JP 6156381 B
[PTL 2] JP 2019-201160 A

### SUMMARY

### Technical Problem

However, formation of a polyimide film on a front electrode complicates production steps, causing a problem of an increase in production costs. The formation also causes problems which reduce ease of assembly, such as an increase in the amount of chip warpage due to polyimide film stress and reduction in solder joinability due to polyimide hardening heat treatment.

To solve the above-described problems, the present disclosure modifies an outermost surface of a front electrode by laser irradiation. An object of the present disclosure is to provide a semiconductor apparatus and a method for producing the same capable of achieving reduction in semiconductor apparatus costs and enhancement in ease of assembly.

### Solution to Problem

The first aspect of the present disclosure is preferably a semiconductor apparatus comprising a front electrode solder-joined portion, solder, a resin sealing material, and a semiconductor device which is mounted underneath the front electrode solder-joined portion, wherein the front electrode solder-joined portion has a first laser-modified portion whose outermost surface is oxidized and roughened, and a first solder-joined region which is joined to the solder, and the laser-modified portion is covered with the resin sealing material.

The second aspect of the present disclosure is preferably a method for producing a semiconductor apparatus including a front electrode solder-joined portion, solder, and a resin sealing material, comprising a step of forming a laser-modified portion by pulse irradiation of a part of the front electrode solder-joined portion with laser light, a step of performing solder joining targeted at the front electrode solder-joined portion, and a step of performing resin sealing using the resin sealing material so as to cover the laser-modified portion.

### Advantageous Effects of Invention

According to the aspects of the present disclosure, it is possible to provide a semiconductor apparatus and a method for producing the same capable of achieving reduction in semiconductor apparatus costs and enhancement in ease of assembly by modifying an outermost surface of a front electrode by laser irradiation.

### BRIEF DESCRIPTION OF DRAWINGS

FIG. 1 is a view showing a sectional view of a semiconductor apparatus according to a first embodiment.

FIG. 2 is a sectional view showing the semiconductor apparatus before laser irradiation according to the first embodiment.

FIG. 3 is a sectional view showing the semiconductor apparatus after laser irradiation according to the first embodiment.

FIG. 4 is a sectional view showing the semiconductor apparatus after solder joining according to the first embodiment.

FIG. 5 is a sectional view showing the semiconductor apparatus after resin sealing according to the first embodiment.

FIG. 6 is a plan view showing the semiconductor device before laser irradiation according to the first embodiment.

FIG. 7 is a plan view showing the semiconductor device after laser irradiation according to the first embodiment.

FIG. 8 is a sectional view showing a semiconductor apparatus according to a fourth embodiment.

FIG. 9 is a sectional view showing a semiconductor apparatus according to a seventh embodiment.

FIG. 10 is a sectional view showing a semiconductor apparatus according to an eighth embodiment.

FIG. 11 is a plan view showing a semiconductor device according to a tenth embodiment.

FIG. 12 is a plan view showing semiconductor device information formation area according to the tenth embodiment.

FIG. 13 is a plan view showing semiconductor device information formation area according to the tenth embodiment.

FIG. 14 is a plan view showing a semiconductor device according to an eleventh embodiment.

FIG. 15 is a sectional view showing a semiconductor apparatus according to the eleventh embodiment.

FIG. 16 is a plan view showing a semiconductor device according to a twelfth embodiment.

FIG. 17 is a plan view showing a semiconductor device according to a thirteenth embodiment.

FIG. 18 is a sectional view showing a semiconductor apparatus before laser irradiation according to a fourteenth embodiment.

FIG. 19 is a sectional view showing the semiconductor apparatus after resin sealing according to the fourteenth embodiment.

FIG. 20 is a plan view showing the back electrode before laser irradiation according to the fourteenth embodiment.

FIG. 21 is a plan view showing the back electrode after laser irradiation according to the fourteenth embodiment.

FIG. 22 is a sectional view showing an end of a semiconductor device before resin sealing according to the fifteenth embodiment.

FIG. 23 is a plan view showing the semiconductor device before resin sealing according to the fifteenth embodiment.

FIG. 24 is a plan view showing a semiconductor device before resin sealing according to a sixteenth embodiment.

### DESCRIPTION OF EMBODIMENTS

### First Embodiment

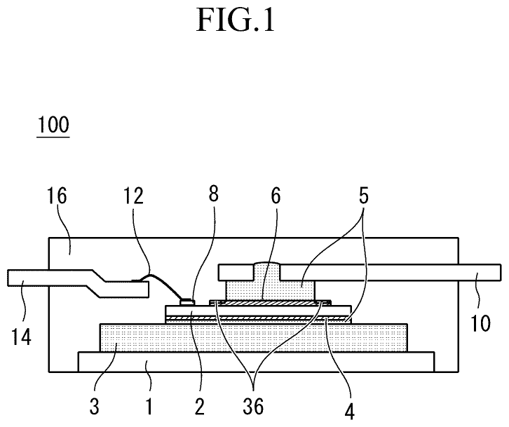

FIG. 1 is a view showing a sectional view of a semiconductor apparatus according to a first embodiment. A semiconductor apparatus 100 includes a semiconductor device 2. The semiconductor device 2 has a back electrode 4 on the back. The back electrode 4 is formed of a metal film and is connected to a base plate 3 having a heat dissipation action, using a conductive joining material 5, such as solder. The base plate 3 is formed of a metal, such as Cu, and is connected to an insulating layer 1.

The semiconductor device 2 has a front electrode solder-joined portion 6 on the front. The front electrode solder-joined portion 6 is formed of a metal film. The front electrode solder-joined portion 6 is an electrode through which a principal current for the semiconductor device 2 is to be passed. The front electrode solder-joined portion 6 is connected to an external electrode 10 which is formed of a metal, such as Cu, using the conductive joining material 5 that is solder.

The semiconductor device 2 has a front electrode wire pad portion 8 on the front. The front electrode wire pad portion 8 is formed of a metal film. The front electrode wire pad portion 8 is used to drive and control the semiconductor device 2. The front electrode wire pad portion 8 is connected to an external electrode 14 which is electrically separated from the front electrode solder-joined portion 6, using a conductive wiring material 12, such as an aluminum wire.

The whole of the semiconductor apparatus 100 is sealed with a sealing material 16 to ensure electrical insulation, environment resistance, and the like. The sealing material 16 is formed of an insulating material which is made of, e.g., epoxy resin.

If a semiconductor apparatus having the above-described structure is subjected to heat stress from a power cycle, a thermal cycle, or the like, thermal stress arising from a difference in coefficient of linear expansion between materials is generated at an end of the front electrode solder-joined portion 6 of the semiconductor device. Upon the generation, interfacial peeling occurs at a front electrode, the conductive joining material, and the sealing material. When the interfacial peeling develops due to repeated thermal stress, a crack appears in a metal film, of which the front electrode of the semiconductor device is formed. To prevent such a metal film crack, a technique for forming a covering film made of polyimide at a front electrode end of a semiconductor device is disclosed in PTL 1 and PTL 2. A metal film crack is suppressed by forming a stress relaxation layer or enhancing adhesion to an underlying metal film by the technique.

However, formation a polyimide film causes problems in terms of production costs and ease of assembly. For this reason, in the semiconductor apparatus 100 according to the present embodiment, an outermost surface of a front electrode is irradiated with laser instead of forming a polyimide film. With this irradiation, a laser-modified portion 18 is formed. This enhances the degree of adhesion at an interface between the front electrode and the sealing material and suppresses peeling at each material interface.

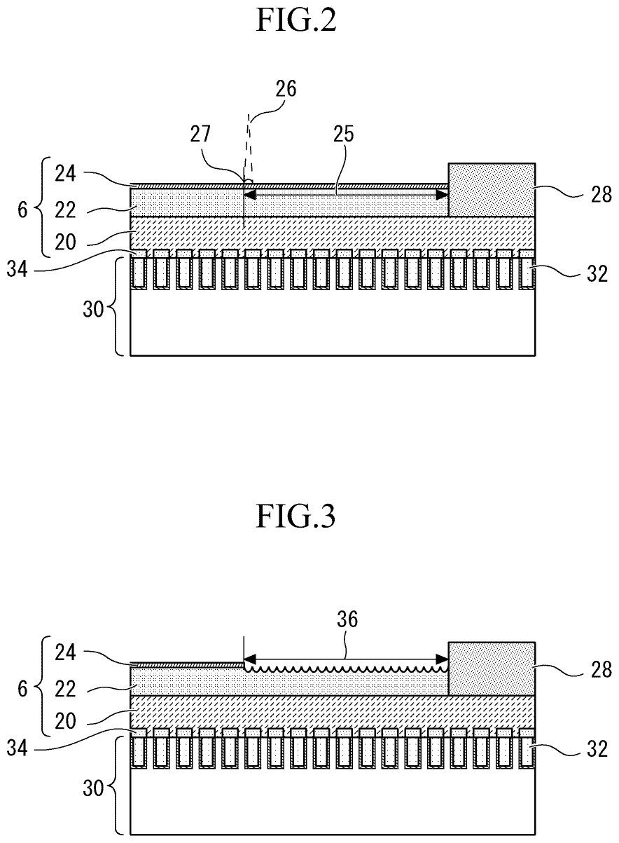

A production process for the semiconductor apparatus 100 will be described. FIG. 2 is a sectional view showing the semiconductor apparatus before laser irradiation according to the first embodiment. The front electrode solder-joined portion 6 of the semiconductor device includes a first metal film 20. The first metal film 20 contains Al and functions as an adhesive film. A second metal film 22 is formed on the first metal film 20. The second metal film 22 contains Ni and functions as a joining film. A third metal film 24 is formed on the second metal film 22. The third metal film 24 contains Au and functions as an antioxidant film.

A laser-irradiated portion 25 refers to a region to be irradiated with laser light 26 at an outermost layer of the front electrode solder-joined portion 6. A machining region 27 refers to a circular region which can be machined in one pulse irradiation operation with the laser light 26. A covering film 28 is formed at a position in contact with ends of the second metal film 22 and the third metal film 24 on the first metal film 20.

A semiconductor substrate 30 is arranged underneath the front electrode solder-joined portion 6. The semiconductor substrate 30 includes trenches 32 filled with poly-Si. Oxide films 34 are formed on the trenches 32.

FIG. 3 is a sectional view showing the semiconductor apparatus after laser irradiation according to the first embodiment. FIG. 3 shows a state after an outermost layer of the third metal film 24 is irradiated with the laser light 26.

A laser-modified portion 36 refers to a region which is irradiated with the laser light 26. In the laser-modified portion 36, thermal energy from the laser light 26 causes solid diffusion of Au and Ni. That is, Au contained in the third metal film 24 diffuses into the second metal film 22, thereby forming a Ni oxide layer at a superficial layer.

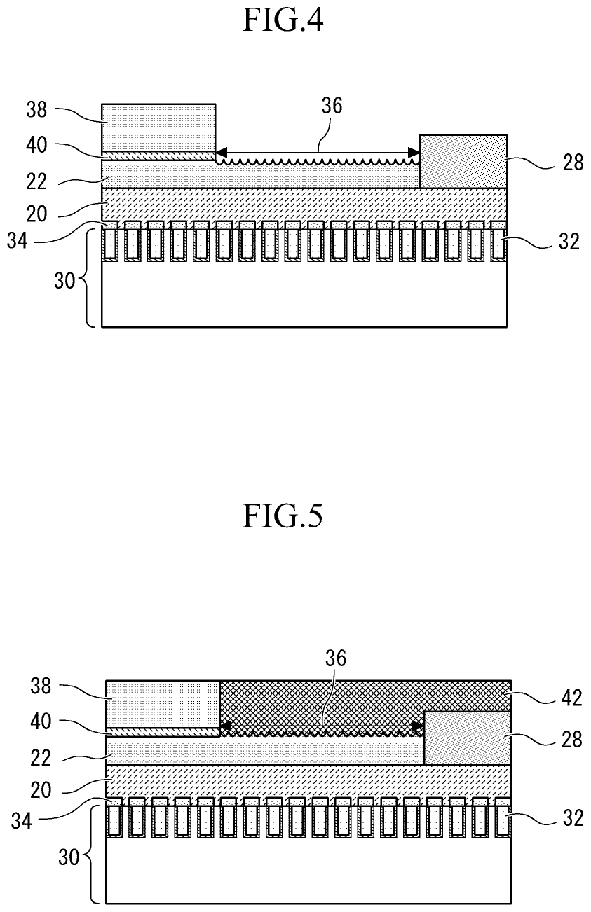

FIG. 4 is a sectional view showing the semiconductor apparatus after solder joining according to the first embodiment. Within a range where solder 38 spreads, an intermetallic compound layer 40 is formed by a reaction with the third metal film 24. Since the Ni oxide layer is formed at the superficial layer in the laser-modified portion 36, the laser-modified portion 36 is inhibited from being wetted with the solder.

In the laser-modified portion 36, the superficial layer is concentrically scraped off by irradiation with pulses of the laser light 26. A region which is to be machined in one pulse irradiation operation is the machining region 27 described earlier. The processing is repeated until the whole of the laser-modified portion 36 is machined. As a result, a surface is roughened. The roughening increases an area of contact between the solder and the front electrode to increase surface tension at an interface between the solder and the front electrode. Thus, wetting with the solder is further inhibited.

At the time of laser machining, a laser species is selected in consideration of characteristics of a material to be irradiated with laser. In the present disclosure, a laser species suitable for Au machining is used. In this case, a size which can be machined in one pulse irradiation operation is a diameter of about several tens of μm because of a laser wavelength. However, if an area of a Ni oxide layer formed by laser irradiation is small, the Ni oxide layer is reduced by use of a solder material high in reduction power for Ni oxidation and a solder joining process. As a result, solder may spread.

In the present embodiment, the machining region 27 are formed to be multi-ringed, thereby performing machining such that the machining region 27 surround an outermost periphery of the front electrode. Since a given or larger area can be secured for the Ni oxide layer, a margin for a reduction action on the Ni oxide layer is increased. As a result, in a solder joining step, the solder does not spread to the laser-modified portion 36. After the solder joining, a Ni oxide layer of a given or larger size remains at the laser-modified portion 36 in an exposed state.

FIG. 5 is a sectional view showing the semiconductor apparatus after resin sealing according to the first embodiment. With the resin sealing being done, the superficial layer of the laser-modified portion 36 is covered with a resin sealing material 42. That is, a region composed of a laser-modified surface and a sealing material interface is formed. As described above, the surface of the laser-modified portion 36 is roughened. For this reason, adhesion strength of an interface between the laser-modified portion 36 and the resin sealing material 42 is enhanced by the anchor effect.

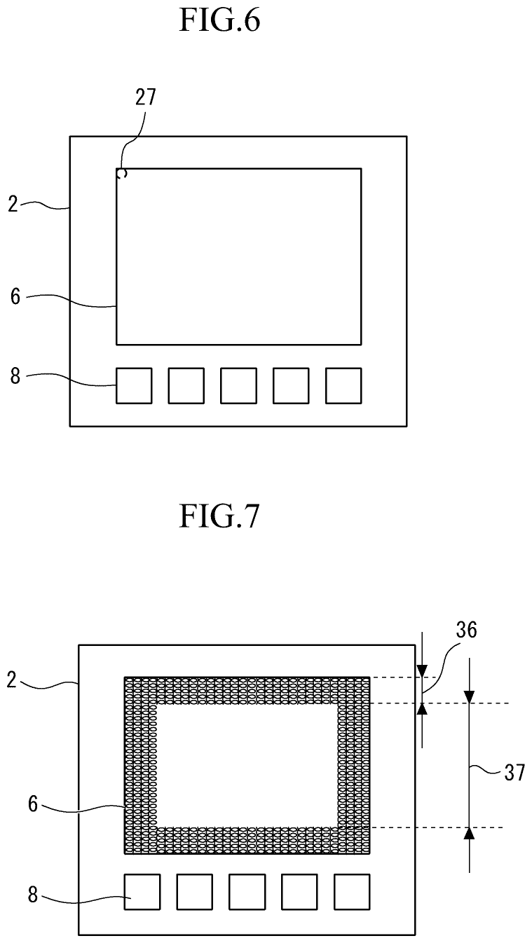

FIG. 6 is a plan view showing the semiconductor device before laser irradiation according to the first embodiment. The semiconductor device 2 includes the front electrode solder-joined portion 6 and the front electrode wire pad portion 8 at a superficial layer. The machining region 27 refers to a region which can be machined in one pulse irradiation operation with the laser light 26.

FIG. 7 is a plan view showing the semiconductor device after laser irradiation according to the first embodiment. The laser-modified portion 36 refers to a region to be irradiated with the laser light 26. Machining can be performed only within the machining region 27 in one pulse irradiation operation with the laser light 26. A range corresponding to the laser-modified portion 36 is machined by repeating pulse irradiation operations. Note that a region left after the laser-modified portion 36 is excluded from the front electrode solder-joined portion 6 is referred to as a solder-joined region 37.

As described above, the present embodiment allows prevention of a metal film crack without formation of a polyimide film. Production steps, such as photoengraving, dispensation and application, and heat treatment, which are needed in the conventional art to form a polyimide film can be omitted. As a result, the costs for production of semiconductor apparatuses can be reduced. Since stress from a polyimide film and polyimide film hardening heat treatment are unnecessary, the prospect of reduction in the amount of chip warpage and enhancement in solder wettability is offered. As a result, enhancement in ease of assembly and improvement in quality can be expected. Additionally, surface roughness and a machining width of the laser-modified portion 36 can be adjusted by laser irradiation conditions. That is, a solder anti-wetting action and adhesion strength to the sealing material can be purposefully controlled, which enhances flexibility in semiconductor apparatus design.

### Second Embodiment

A second embodiment is different from the first embodiment in that machining region 27 are arranged at fixed intervals. If the machining region 27 are arbitrarily arranged in the semiconductor apparatus according to the first embodiment, an unirradiated portion appears at a part in the laser-modified portion 36. In the unirradiated portion, a surface of the third metal film 24 remains exposed. For this reason, at the time of sealing with the resin sealing material 42, an interface between the third metal film 24 and the resin sealing material 42 is formed in each of some regions to reduce adhesion strength.

Under the above-described circumstances, in the present embodiment, the machining region 27 are arranged at fixed intervals so as to overlap, thereby preventing appearance of an unirradiated portion. As a result, an interface between a laser-modified portion 36 and a resin sealing material 42 is uniformly formed. This enhances adhesion strength and allows achievement of increased reliability of a semiconductor apparatus.

### Third Embodiment

A third embodiment is different from the previous embodiments in that a width of a laser-modified portion 36 is set to at least 100 μm. In the semiconductor apparatus according to the first embodiment, the Ni oxide layer at the surface of the laser-modified portion 36 may be reduced in the solder joining step. In this case, solder spreads across the laser-modified portion 36 to narrow a width of the laser-modified portion 36. If the width narrows by a given or larger amount, a region where the laser-modified portion 36 and the resin sealing material 42 are in contact narrows after sealing with the resin sealing material 42. This becomes a factor in reducing adhesion strength.

Generally, if reduction power for Ni oxidation in a solder joining step is high, a phenomenon is confirmed in which Ni oxidation is reduced in a region measuring several tens of μm of a laser-modified portion in a solder major joined portion of a front electrode and solder spreads. For this reason, formation is performed such that a width of a laser-modified portion is set to at least 100 μm. Since a region where the laser-modified portion and a sealing material are in contact can be stably secured, adhesion strength is enhanced, and increased reliability of a semiconductor apparatus can be achieved.

### Fourth Embodiment

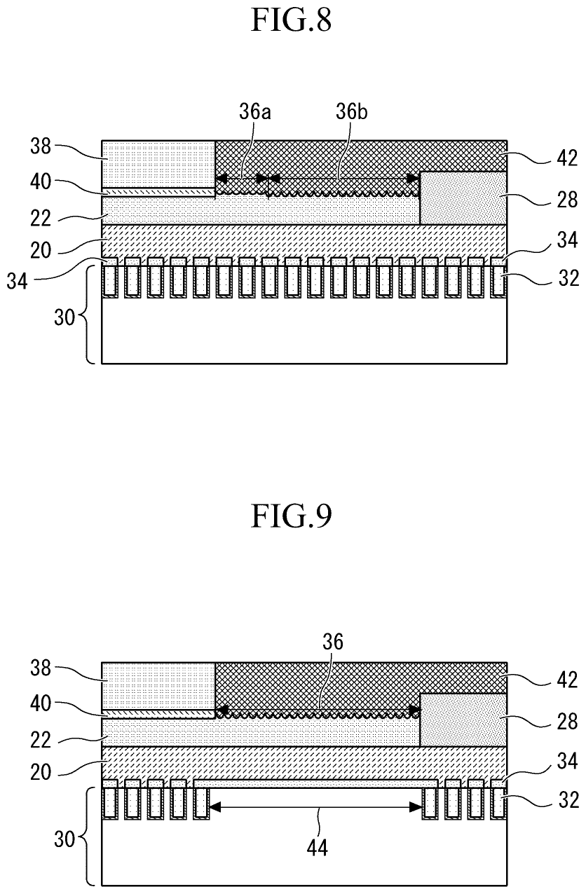

FIG. 8 is a sectional view showing a semiconductor apparatus according to a fourth embodiment. The fourth embodiment is different from the previous embodiments in that an energy density to be given to a laser-modified portion 36 is set different for each region.

In the semiconductor apparatus according to the first embodiment, energy of laser to be applied needs to be increased to enhance a laser modification effect. Upon the increase, influence of the energy reaches a non-laser-irradiated region, and the second metal film 22 is deposited. As a result, a surface may be oxidized to reduce solder wettability.

Under the above-described circumstances, in the present embodiment, an energy density of laser to be applied is reduced only in a region in contact with a front electrode solder-joined portion 6. That is, an energy density of laser to be applied to a laser-modified portion 36a is set smaller than that for a laser-modified portion 36b. This makes it possible to minimize influence of reduction in solder wettability of a non-laser-irradiated region. Even if the energy density is reduced, a surface of the laser-modified portion 36a becomes an Ni oxide layer. Thus, solder does not spread across the laser-modified portion 36a in a solder joining step. Adhesiveness of an interface between the laser-modified portion 36b and a resin sealing material 42 is not impaired by maintaining the energy density for laser to be applied to the laser-modified portion 36b.

### Fifth Embodiment

A fifth embodiment is different from the previous embodiments in that laser light absorptance is set different for each metal film. Consider a case where laser irradiation energy is too high or laser light absorptance of the first metal film 20 or the second metal film 22 is higher than that of the third metal film 24 in the semiconductor apparatus according to the first embodiment. In this case, since a metal film melts into a semiconductor substrate bulk due to heat generated by laser irradiation, an abnormality occurs in electrical characteristics of a semiconductor device.

Under the above-described circumstances, in the present embodiment, a front electrode is formed such that laser light absorptance of a third metal film 24 is higher than those of a first metal film 20 and a second metal film 22. As a result, when an outermost surface of the third metal film 24 is irradiated with laser, heat generated in the first metal film 20 and the second metal film 22 that are underlayers reduces. This can reduce the risk of a metal film melting with heat from laser irradiation, damage to a semiconductor device can be lowered.

### Sixth Embodiment

A sixth embodiment is different from the previous embodiments in that the sum of thicknesses of a first metal film 20 and a second metal film 22 is set to at least 1 μm and that a thickness of a third metal film 24 is set not more than 0.2 μm.

In the semiconductor apparatus according to the first embodiment, an abnormality occurs in electrical characteristics of the semiconductor device due to heat generated by laser irradiation, as described earlier. Under the circumstances, in the present embodiment, the sum of the thicknesses of the first metal film 20 and the second metal film 22 is set to at least 1 μm, and the thickness of the third metal film 24 is set not more than 0.2 μm. Since this setting makes a film to be subjected to laser machining thin and a film not to be subjected to laser machining thick, a Ni oxide layer can be formed with low power. As a result, damage to a semiconductor device from heat at the time of laser machining can be lowered.

### Seventh Embodiment

FIG. 9 is a sectional view showing a semiconductor apparatus according to a seventh embodiment. The seventh embodiment is different from the previous embodiments in that an invalid cell region 44 is arranged immediately below a laser-modified portion 36.

In the semiconductor apparatus according to the first embodiment, an abnormality occurs in electrical characteristics of the semiconductor device due to heat generated by laser irradiation, as described earlier. Under the circumstances, in the present embodiment, the invalid cell region 44 is arranged immediately below the laser-modified portion 36. In the invalid cell region 44, trenches 32 and oxide films 34 which are needed to function as a semiconductor device are not mounted. Since the numbers of trenches 32 and oxide films 34 that are influenced by heat at the time of laser machining reduce, damage to a semiconductor device function in the whole semiconductor apparatus can be lowered.

### Eighth Embodiment

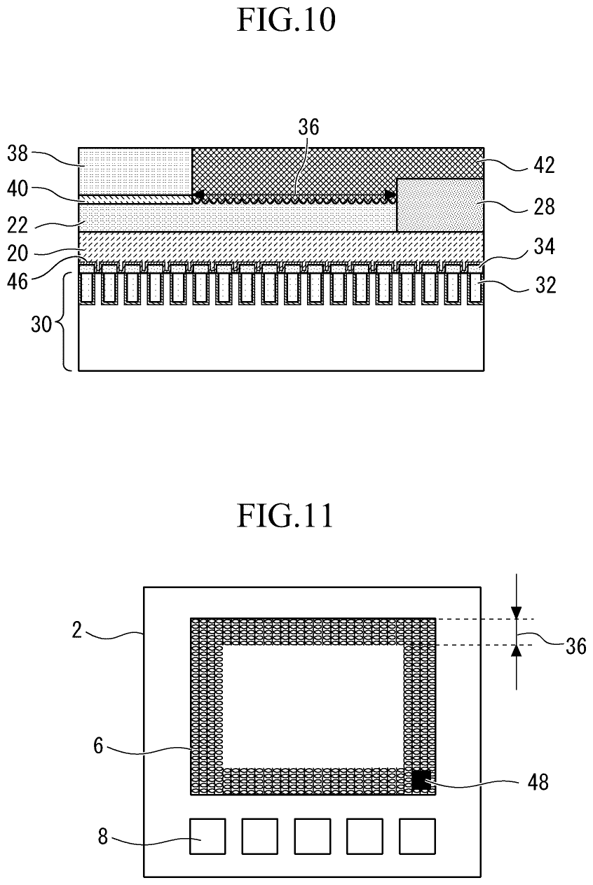

FIG. 10 is a sectional view showing a semiconductor apparatus according to an eighth embodiment. The eighth embodiment is different from the previous embodiments in that a barrier metal layer 46 is provided at a boundary between a first metal film 20 and oxide films 34.

In the semiconductor apparatus according to the first embodiment, an abnormality occurs in electrical characteristics of the semiconductor device due to heat generated by laser irradiation, as described earlier. Under the circumstances, in the present embodiment, the barrier metal layer 46 is provided at the boundary between the first metal film 20 and the oxide film 34. Since Al, of which the first metal film 20 is formed, can be prevented from solid-diffusing into a semiconductor substrate interface, damage to a semiconductor device from heat at the time of laser machining can be lowered.

### Ninth Embodiment

A ninth embodiment is different from the previous embodiments in that a covering film 28 is formed so as to increase reflectance for laser light 26. In the semiconductor apparatus according to the first embodiment, the covering film 28 is arranged at an outermost peripheral portion of the front electrode solder-joined portion 6. An oxide film, an insulating film, or the like may be arranged underneath the covering film 28. In this case, a surface of the oxide film or the insulating film may be damaged by irradiation with the laser light 26.

Under the above-described circumstances, in the present embodiment, the covering film 28 is formed so as to increase the reflectance for the laser light 26. A polyimide film with a low refractive index can be given as an example of a film with a high reflectance for the laser light 26. Since damage to an oxide film or an insulating film from the laser light 26 can be minimized, improvement in quality of the semiconductor apparatus can be expected.

### Tenth Embodiment

FIG. 11 is a plan view showing a semiconductor device according to a tenth embodiment. The tenth embodiment is different from the previous embodiments in that a semiconductor device information formation area 48 is provided at a part in a laser-modified portion 36.

Since the whole region of the laser-modified portion 36 is irradiated with the laser light 26 in the semiconductor apparatus according to the first embodiment, a laser irradiation time lengthens. Under the circumstances, in the present embodiment, the semiconductor device information formation area 48 is provided at a part in the laser-modified portion 36. Only a portion where semiconductor device information is to be printed is irradiated with laser in the semiconductor device information formation area 48, unlike in the laser-modified portion 36. Since the number of irradiation pulses of laser reduces, a laser irradiation time can be shortened.

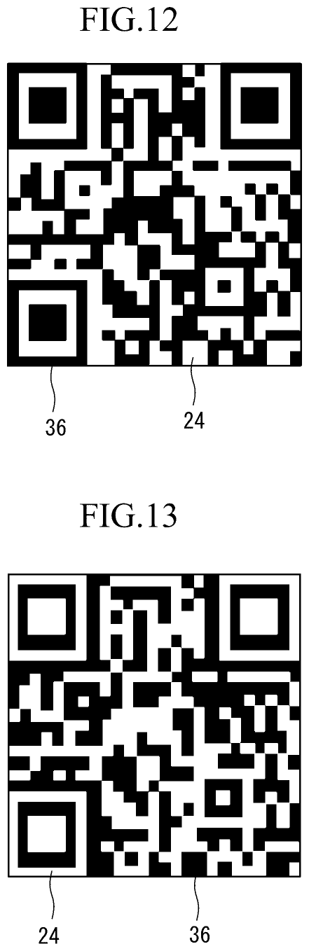

FIGS. 12 and 13 are plan views showing semiconductor device information formation areas according to the tenth embodiment. FIG. 12 shows a case where a two-dimensional code is represented with the laser-modified portion 36. That is, the two-dimensional code is represented with the laser-modified portion 36 indicated in black and third metal film 24 indicated in white. FIG. 13 shows a case where a two-dimensional code is represented in laser-unirradiated regions. That is, the two-dimensional code is represented with the laser-modified portion 36 indicated in white and the third metal film 24 indicated in black. In either case, enhancement of traceability of the semiconductor device can be achieved by printing semiconductor device information by laser irradiation.

Besides semiconductor device information, for example, a mark indicating position information of the semiconductor device can be printed. In this case, in an assembly step of a semiconductor apparatus, the position information of the semiconductor device can be recognized on the apparatus side. Thus, visibility of the semiconductor device is enhanced, and enhancement of ease of assembly of the semiconductor apparatus can be expected.

### Eleventh Embodiment

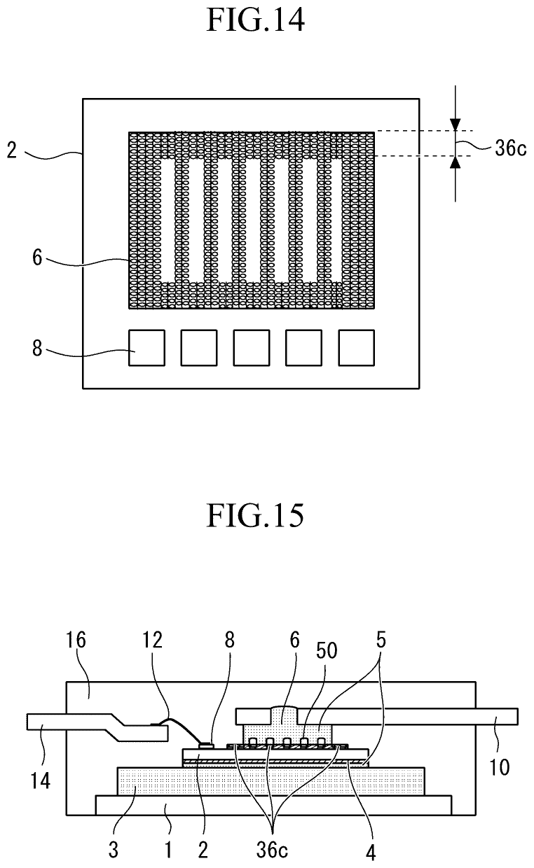

FIG. 14 is a plan view showing a semiconductor device according to an eleventh embodiment. The eleventh embodiment is different from the previous embodiments in that laser is applied in a striped pattern.

Since the front electrode solder-joined portion 6 is continuous in the semiconductor apparatus according to the first embodiment, thermal stress may be generated at a solder joining interface. Under the circumstances, in the present embodiment, a solder joining interface is divided into a plurality of pieces by applying laser in a striped pattern, as in a laser-modified portion 36c. This allows dispersion of thermal stress generated in a solder joining interface at the time of a power cycle test.

FIG. 15 is a sectional view showing a semiconductor apparatus according to the eleventh embodiment. The laser-modified portion 36c is formed in a striped pattern, thereby forming holes 50 at a lower portion of a front electrode solder-joined portion 6. That is, since a solder joining interface is divided into a plurality of pieces, thermal stress generated at the time of a power cycle test can be dispersed.

### Twelfth Embodiment

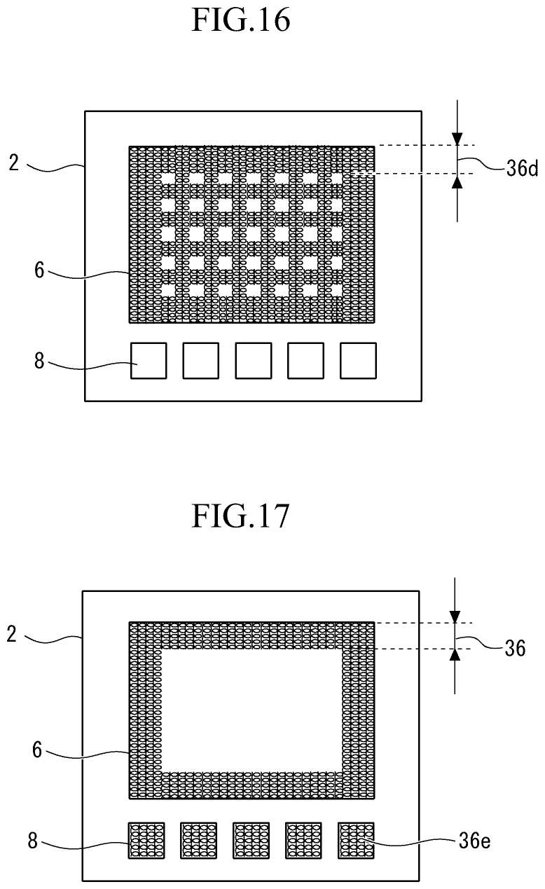

FIG. 16 is a plan view showing a semiconductor device according to a twelfth embodiment. The twelfth embodiment is different from the previous embodiments in that laser is applied in a grid pattern.

Since the front electrode solder-joined portion 6 is continuous in the semiconductor apparatus according to the first embodiment, thermal stress may be generated at a solder joining interface. Under the circumstances, in the present embodiment, a solder joining interface is divided into a plurality of pieces by applying laser in a grid pattern, as in a laser-modified portion 36d. This allows dispersion of thermal stress generated in a solder joining interface at the time of a power cycle test.

### Thirteenth Embodiment

FIG. 17 is a plan view showing a semiconductor device according to a thirteenth embodiment. The thirteenth embodiment is different from the previous embodiments in that laser is also applied to a front electrode wire pad portion 8.

In the semiconductor apparatus according to the first embodiment, when solder joining is performed in a step of assembling the semiconductor device 2, solder may spatter on the front electrode wire pad portion 8. When bonding is subsequently performed with, e.g., an aluminum wire, poor aluminum wire joining may occur.

Under the above-described circumstances, in the present embodiment, laser is applied to a surface of the front electrode wire pad portion 8 to form a laser-modified portion 36e. Since wetting of the front electrode wire pad portion 8 with solder can be suppressed in the case of a solder spatter, yield enhancement in an assembly step can be expected.

### Fourteenth Embodiment

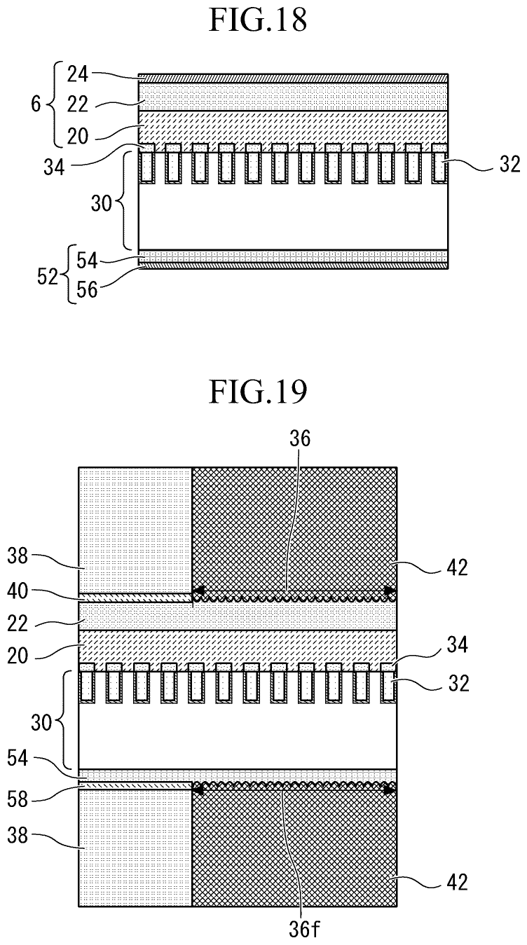

FIG. 18 is a sectional view showing a semiconductor apparatus before laser irradiation according to a fourteenth embodiment. The fourteenth embodiment is different from the previous embodiments in that laser is also applied to a back electrode.

A semiconductor device according to the fourteenth embodiment includes a back electrode 52. The back electrode 52 has a fourth metal film 54 and a fifth metal film 56. The back electrode 52 is joined to a radiator plate which is formed of a conductive material, such as Cu, with solder in an assembly step. As a result, a solder-joined region is formed to follow a shape of the back electrode 52.

Consider a case where a thermal cycle test which applies thermal stress is conducted on the above-described semiconductor apparatus. In this case, thermal stress concentrates on the back electrode and the solder-joined region due to a difference in coefficient of linear expansion between materials, and a corner portion of the solder-joined region peels off. Since the peeling causes a crack in the solder, the semiconductor apparatus may deteriorate. Under the circumstances, in the present embodiment, laser is also applied to the back electrode 52.

FIG. 19 is a sectional view showing the semiconductor apparatus after resin sealing according to the fourteenth embodiment. FIG. 19 shows the semiconductor apparatus after solder joining and resin sealing on a front electrode side and a back electrode side.

When laser is applied to a part on the back electrode side, a laser-modified portion 36f is formed at a superficial layer of the fourth metal film 54. Although solder joining is subsequently performed, solder 38 does not spread on the laser-modified portion 36f. Since the solder 38 spreads over a portion other than the laser-modified portion 36f, solder joining is performed. At this time, an intermetallic compound layer 58 is formed. When resin sealing is subsequently performed, the laser-modified portion 36f is covered with a resin sealing material 42.

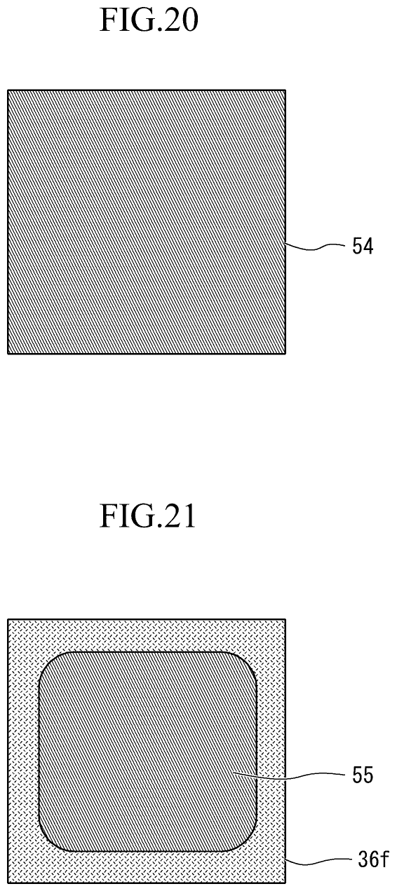

FIG. 20 is a plan view showing the back electrode before laser irradiation according to the fourteenth embodiment. FIG. 21 is a plan view showing the back electrode after laser irradiation according to the fourteenth embodiment. At the time of forming the laser-modified portion 36f, laser irradiation is performed such that each corner portion of an unirradiated portion is rounded. The unirradiated portion becomes a solder-joined region 55. This allows dispersion of stress on the corner portion of the solder-joined region and prevention of peeling of the corner portion.

Note that although an example in which laser irradiation is performed at a back electrode such that each corner portion of an unirradiated portion is rounded is illustrated here, laser irradiation may be performed in another region such that each corner portion of an unirradiated portion is rounded.

### Fifteenth Embodiment

A fifteenth embodiment is different from the previous embodiments in that an outermost peripheral portion of a semiconductor substrate 30 is irradiated with laser. In the semiconductor apparatus according to the first embodiment, shearing stress from the resin sealing material 42 is applied to an outermost periphery of the semiconductor device 2 when thermal stress, such as a thermal cycle, is applied. Upon the application, an interface between the resin sealing material 42 and the semiconductor device 2 may peel off.

Under the above-described circumstances, in the present embodiment, the outermost peripheral portion of the semiconductor substrate 30 is irradiated with laser. With this irradiation, interface adhesion strength between the resin sealing material 42 and the semiconductor substrate 30 is enhanced. This allows achievement of increased reliability of a semiconductor apparatus.

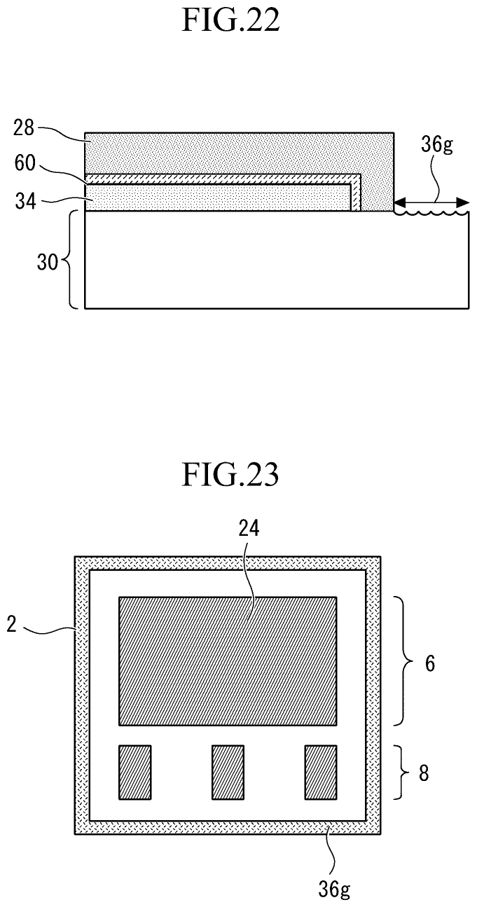

FIG. 22 is a sectional view showing an end of a semiconductor device before resin sealing according to the fifteenth embodiment. An oxide film 34 is formed on the semiconductor substrate 30. The oxide film 34 is covered with an overcoat 60. The overcoat 60 is covered with a covering film 28.

A laser-modified portion 36g is formed by laser irradiation at the outermost peripheral portion of the semiconductor substrate 30. The covering film 28 does not cover an outermost peripheral portion of a semiconductor device 2. For this reason, in a subsequent resin sealing step, the interface adhesion strength between the resin sealing material 42 and the semiconductor substrate 30 is enhanced by effects of the laser-modified portion 36g.

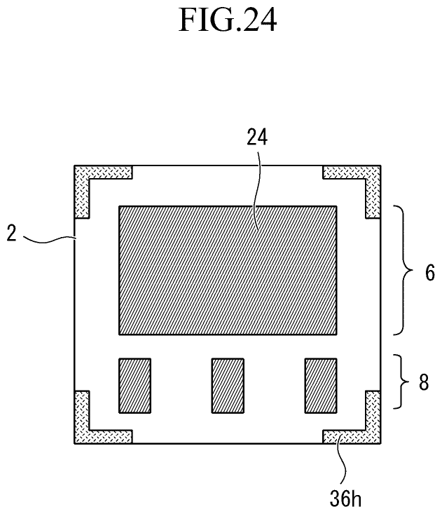

FIG. 23 is a plan view showing the semiconductor device before resin sealing according to the fifteenth embodiment. The laser-modified portion 36g is formed over the whole outermost peripheral portion of the semiconductor device 2. This allows enhancement of the interface adhesion strength between the resin sealing material 42 and the semiconductor substrate 30.

### Sixteenth Embodiment

FIG. 24 is a plan view showing a semiconductor device before resin sealing according to a sixteenth embodiment. The sixteenth embodiment is different from the previous embodiments in that each corner portion of a semiconductor substrate 30 is irradiated with laser. Shearing stress described in the fifteenth embodiment concentrates on each corner portion of a semiconductor device. Under the circumstances, in the present embodiment, the corner portion of the semiconductor substrate 30 is irradiated with laser. That is, a laser-modified portion 36h is formed at each corner portion of the semiconductor substrate 30. With this formation, interface adhesion strength between a resin sealing material 42 and the semiconductor substrate 30 is locally enhanced. This allows achievement of increased reliability of a semiconductor apparatus.

### Seventeenth Embodiment

A seventeenth embodiment is different from the previous embodiments in that a semiconductor substrate 30 is formed of silicon carbide.

A currently most widely available material for a semiconductor substrate is silicon. Silicon carbide is 2.6 times larger in modulus of longitudinal elasticity and 1.5 times larger in coefficient of linear expansion than a silicon substrate, and adhesion strength to a resin sealing material is ⅔ or less that of the silicon substrate. For this reason, if a power cycle test is conducted on a conventional semiconductor apparatus using a silicon carbide substrate, interfacial peeling between a sealing material and a semiconductor device surface is likely to occur. That is, reliability of the semiconductor apparatus may reduce.

However, in a semiconductor apparatus according to the present disclosure, adhesiveness between a sealing material and a semiconductor device surface is expected to be enhanced by roughening by laser modification. For this reason, even if a silicon carbide substrate is used, increased reliability of the semiconductor apparatus can be expected.

In a conventional semiconductor apparatus, a covering film, such as a polyimide film, is used as a stress buffer layer. For this reason, a width of the stress buffer layer needs to be determined with consideration of not only material-induced features, such as viscosity and photosensitive characteristics but also coater-induced variation in accuracy, such as an application position, an air pressure, and an application amount.

However, in the semiconductor apparatus according to the first embodiment, dimensions of a machining region can be determined only with consideration of laser machining accuracy. That is, machining variation can be reduced compared with a conventional semiconductor apparatus. For this reason, reduction in semiconductor apparatus costs can be expected more than ever before by use of expensive silicon carbide for a semiconductor substrate of the present disclosure.

Note that although a case where a semiconductor substrate is formed of silicon carbide is illustrated in the present embodiment, the semiconductor substrate may be formed of a wide-bandgap semiconductor with a wide bandgap, like silicon carbide. An example of the wide-bandgap semiconductor is a GaN-based material or diamond.

### REFERENCE SIGNS LIST

2 semiconductor device
4 back electrode
6 solder-joined portion
8 wire pad portion
16 sealing material 16
18 laser-modified portion
26 laser light
27 machining region
28 covering film
34 oxide films
36 laser-modified portion
36a laser-modified portion
36b laser-modified portion
36c laser-modified portion
36d laser-modified portion
36e laser-modified portion
36f laser-modified portion
36g laser-modified portion
36h laser-modified portion
37 solder-joined region
42 resin sealing material
44 invalid cell region
46 barrier metal layer
48 semiconductor device information formation area
52 back electrode
55 solder-joined region
100 semiconductor apparatus

1. A semiconductor apparatus comprising a front electrode solder-joined portion, solder, a resin sealing material, and a semiconductor device which is mounted underneath the front electrode solder-joined portion,
wherein the front electrode solder-joined portion has
a first laser-modified portion whose outermost surface is oxidized and roughened, and
a first solder-joined region which is joined to the solder, and
the laser-modified portion is covered with the resin sealing material.

2. The semiconductor apparatus according to claim 1, wherein
the first laser-modified portion is formed by pulse irradiation with laser light.

3. The semiconductor apparatus according to claim 2, wherein
the first laser-modified portion
is formed by arranging a plurality of machining regions, each of which can be machined in one operation of the pulse irradiation, such that the machining regions surround an outer peripheral portion of the front electrode solder-joined portion.

4. The semiconductor apparatus according to claim 3, wherein
the machining regions are arranged at fixed intervals such that adjacent ones of the machining regions overlap with each other.

5. The semiconductor apparatus according to claim 1, wherein
a width of the first laser-modified portion is not less than 100 μm.

6. The semiconductor apparatus according to claim 1, wherein
the first laser-modified portion is lower in degree of oxidation and roughening in a region farther from an outermost peripheral portion of the front electrode solder-joined portion than in a closer region.

7. The semiconductor apparatus according to claim 1, wherein
the semiconductor device includes a valid cell region with functionality and an invalid cell region without functionality, and
the invalid cell region is located immediately below the first laser-modified portion.

8. The semiconductor apparatus according to claim 1, wherein
the semiconductor device has an oxide film at a superficial layer, and
a barrier metal layer is formed at a boundary between the oxide film and the front electrode solder-joined portion.

9. The semiconductor apparatus according to claim 2, further comprising a covering film which covers an outer edge of the front electrode solder-joined portion, wherein
the covering film is formed of a material which is higher in reflectance for the laser light than the front electrode solder-joined portion.

10. The semiconductor apparatus according to claim 1, wherein
the first laser-modified portion has a semiconductor device information formation area where a desired code is embedded.

11. The semiconductor apparatus according to claim 1, wherein
the first solder-joined region is divided into a plurality of pieces.

12. The semiconductor apparatus according to claim 11, wherein
the first laser-modified portion is formed in a striped pattern at a superficial layer of the front electrode solder-joined portion.

13. The semiconductor apparatus according to claim 11, wherein
the first laser-modified portion is formed in a grid pattern at a superficial layer of the front electrode solder-joined portion.

14. The semiconductor apparatus according to claim 1, further comprising a front electrode wire pad portion, wherein
the front electrode wire pad portion has a second laser-modified portion whose outermost surface is oxidized and roughened.

15. The semiconductor apparatus according to claim 1, further comprising
a back electrode, wherein
the back electrode has
a third laser-modified portion whose outermost surface is oxidized and roughened, and
a second solder-joined region which is joined to the solder, and
a corner portion of the second solder-joined region is processed to be rounded.

16. The semiconductor apparatus according to claim 1, wherein
the semiconductor device has, at an outermost peripheral portion, a fourth laser-modified portion whose outermost surface is oxidized and roughened.

17. The semiconductor apparatus according to claim 1, wherein
the semiconductor device has, at a corner portion of an outermost peripheral portion, a fifth laser-modified portion whose outermost surface is oxidized and roughened.

18. The semiconductor apparatus according to claim 1, wherein
the semiconductor device is formed of a wide-bandgap semiconductor.

19. The semiconductor apparatus according to claim 18, wherein
the wide-bandgap semiconductor is silicon carbide, a GaN-based material, or diamond.

20. A method for producing a semiconductor apparatus including a front electrode solder-joined portion, solder, and a resin sealing material, comprising:
a step of forming a laser-modified portion by pulse irradiation of a part of the front electrode solder-joined portion with laser light;
a step of performing solder joining targeted at the front electrode solder-joined portion; and
a step of performing resin sealing using the resin sealing material so as to cover the laser-modified portion.

21. The method for producing the semiconductor apparatus according to claim 20, wherein
the front electrode solder-joined portion has a metal film as an upper layer and a metal film as a lower layer, and
the metal film as the lower layer has higher laser light absorptance than the metal film as the upper layer.

22. The method for producing the semiconductor apparatus according to claim 20, wherein
the front electrode solder-joined portion has a metal film as an upper layer and a metal film as a lower layer,
a thickness of the metal film as the lower layer is not less than 1 μm, and
a thickness of the metal film as the upper layer is not more than 0.2 μm.
